(19) United States
(12) Patent Application Publication
(10) Pub. No.: US 2022/0205739 A1
(43) Pub. Date: Jun. 30, 2022

(54) HEAT SINK STRUCTURE

(71) Applicant: ASIA VITAL COMPONENTS (CHINA) CO., LTD., Shenzhen (CN)

(72) Inventors: Dan-Jun Chen, Shenzhen (CN); Guo-Hui Li, Shenzhen (CN); Chuan-Wen Huang, Shenzhen (CN)

(21) Appl. No.: 17/137,349

(22) Filed: Dec. 30, 2020

(51) Int. Cl. F28F 3/06

(52) U.S. Cl. CPC F28F 3/06

(57) ABSTRACT

A heat sink structure includes a plurality of radiation fins and a base. Each of the radiation fins has a connecting end and a free end, and internally defines a chamber extended between the connecting end and the free end for filling a working fluid therein. The base has an upper connecting surface provided with a plurality of connecting sections and a lower heat receiving surface in contact with a heat source. The connecting ends of the radiation fins are integrally connected to the connecting sections of the base in one-to-one correspondence through overmolding, so as to eliminate thermal resistance between the radiation fins and the base.

### FIELD OF THE INVENTION

The present invention relates to a heat sink structure, and more particularly, to a heat sink structure that has radiation fins integrally connected to a base through overmolding to avoid thermal resistance between the base and the radiation fins.

### BACKGROUND OF THE INVENTION

Currently, the conventional die-cast heat sink structure has limited heat dissipation performance when it is applied to a 5G product or apparatus, such as a communication chassis or a communication device, and the product using it outdoors are difficult to maintain because the die-cast heat sink structure is big in volume and heavy in weight. To upgrade the heat dissipation ability of the product and to reduce the overall weight of the product, high-efficiency radiation fins have been introduced into the market. In this case, the radiation fins are usually glued to a base using an epoxy adhesive or are connected to the base by riveting. In view that the 5G products are often used outdoors, the epoxy adhesive connecting the radiation fins to the base is subjected to the risk of aging and accordingly, not perfect for use. Therefore, epoxy adhesive is not frequently applied to 5G products. On the other hand, riveting is presently the main way in the market for connecting the high-efficiency radiation fins to the base. However, there would be clearance between the contact surfaces of two metal members connected together in this natural way and air in the clearance would inevitably cause high thermal resistance between the riveted radiation fins and base. While the high-efficiency radiation fins provide considerably good heat dissipation performance, the clearance at the riveted joint prevents the heat from being completely transferred from the heat-producing elements to the radiation fins via the base of the heat sink structure.

The high-efficiency radiation fins respectively have an internally defined chamber, in which a liquid or a gaseous working fluid is filled. Since the chambers in the radiation fins are in a vacuum state, the working liquid or gas having a lower boiling point can be vaporized earlier to enable upgraded heat transfer efficiency.

Since the high-efficiency radiation fins have the working liquid or gas filled in the chambers, attention must be paid when the radiation fins are connected to the base in order to avoid damaging the vacuum tightness of the chambers. Further, when a thermal machining process is necessary, high attention must also be paid to see whether the working fluid in the chambers is vaporized at high temperature or not, lest the working fluid should lose its heat exchange function.

It is therefore very important for the high-efficiency radiation fins to be stably connected to the base of the heat sink structure without forming any clearance between them.

### SUMMARY OF THE INVENTION

To effectively solve the problem in the conventional heat sink structure, a primary object of the present invention is to provide a heat sink structure that has a plurality of radiation fins and a base integrally connected to one another to eliminate thermal resistance between them.

To achieve the above and other objects, the heat sink structure according to the present invention includes a plurality of radiation fins and a base. Each of the radiation fins has a connecting end and a free end, and internally defines a chamber extended between the connecting end and the free end for filling a working fluid therein. The base has an upper and a lower side serving as a connecting surface and a heat receiving surface, respectively. The heat receiving surface is in contact with a heat source, and the connecting surface is integrally connected to the connecting ends of the radiation fins through overmolding.

The connecting surface of the base has a plurality of connecting sections integrally formed thereon. The connecting ends of the radiation fins are extended into and accordingly integrally connected to the connecting sections through overmolding, such that the connecting ends are enclosed in the connecting sections in one-to-one correspondence, allowing the radiation fins to be stably and integrally connected to the base.

The working fluid can be a gas or a liquid.

The radiation fins and the base can be made of the same or different materials.

The radiation fins are subjected to working fluid filling and vacuum evacuation only after the radiation fins have been integrally connected to the base through overmolding.

Since the radiation fins are integrally connected to the base through overmolding before the radiation fins are subjected to working fluid filling and vacuum evacuation, the working fluid in the internal chambers of the radiation fins would not be vaporized at the high temperature when the radiation fins are connected to the base through overmolding. Thus, the radiation fins can be stably connected to the base to eliminate thermal resistance between them.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view showing a heat sink structure according to a preferred embodiment of the present invention; and

FIG. 2 is an assembled sectional view of the heat sink structure of FIG. 1.

### DETAILED DESCRIPTION OF THE PREFERRED EMBODIMENTS

The present invention will now be described with some preferred embodiments thereof and by referring to the accompanying drawings.

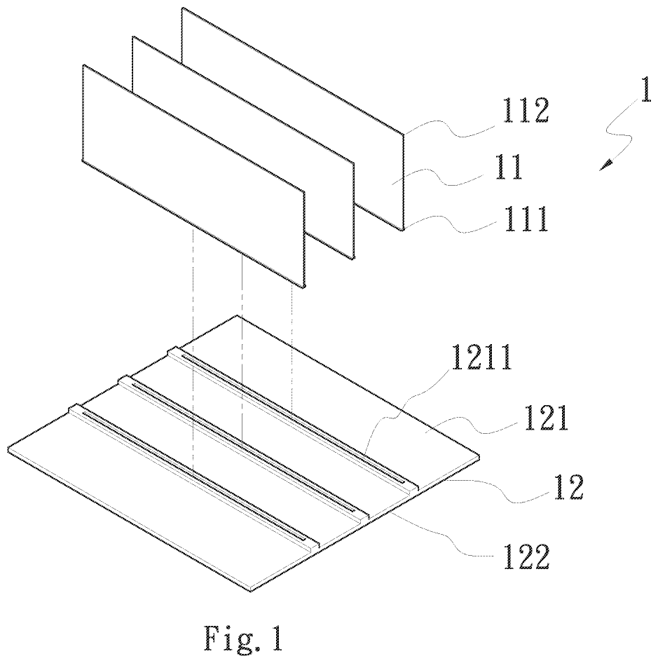

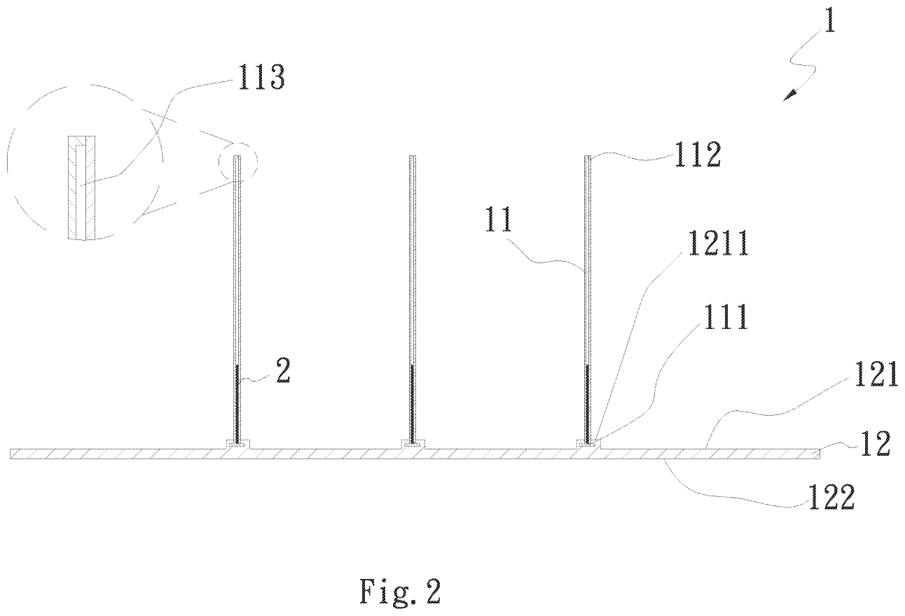

Please refer to FIGS. 1 and 2, which are exploded perspective and assembled sectional views, respectively, of a heat sink structure 1 according to a preferred embodiment of the present invention. As shown, the heat sink structure 1 includes a plurality of radiation fins 11 and a base 12.

Each of the radiation fins 11 has a connecting end 111 and a free end 112 and internally defines a vacuum chamber 113 that is extended between the connecting end 111 and the free end 112. A working fluid 2 is filled in the chamber 113, and the working fluid 2 can be a gas or a liquid.

The base 12 has an upper and a lower side, which serve as a connecting surface 121 and a heat receiving surface 122, respectively. The heat receiving surface 122 is in contact with at least one heat source, while the connecting surface 121 faces toward the connecting ends 111 of the radiation fins 11 and has a plurality of connecting sections 1211 formed thereon. The connecting ends 111 of the radiation fins 11 are extended into and accordingly integrally connected to the connecting sections 1211 through overmolding. In other words, the connecting ends 111 are enclosed in the connecting sections 1211 in one-to-one correspondence. The connecting ends 111 may be respectively in the form of an inverted letter T or a letter L, or in any other suitable geometric shape. In the preferred embodiment, the connecting ends are respectively non-restrictively shown as an inverted letter T, and the connecting sections 1211 completely enclose the inverted T-shaped connecting ends 111 through overmolding, so that the radiation fins 11 are stably and integrally connected to the base 12 without forming any clearance between the connecting ends 111 and the base 12. With the special design of the connecting ends 111, the radiation fins 11 are protected against the risk of being extracted from the connecting sections 1211 on the base 12.

The radiation fins 11 and the base 12 may be made of the same or different materials. The material suitable for making the radiation fins 11 and the base 12 may be any one of copper, aluminum, stainless steel, or a combination thereof. It is noted the radiation fins 11 are connected to the base 12 through overmolding before the chambers 113 thereof are subjected to the procedures of working fluid filling and vacuum evacuation.

The main purpose of overmolding the radiation fins 11 and the base 12 before the working fluid filling and the vacuum evacuation is to prevent the working fluid 2 in the chamber 113 of the radiation fins 11 from being vaporized at the high temperature when the radiation fins 11 are connected to the base 12 through overmolding, in order to maintain good heat exchange function that is achieved through efficient vapor-liquid circulation of the working fluid 2 in the radiation fins 11. Therefore, it is preferable to connect the radiation fins 11 to the base 12 through overmolding before the radiation fins 11 are filled with the working fluid 2 and vacuum evacuated. Then, the radiation fins 11 are sealed.

The present invention is characterized in providing a type of radiation fins 11 for highly-efficient heat transfer. More specifically, the radiation fins 11 respectively have an internal chamber 113 filled with the working fluid 2, which may be a gas or a liquid; and the working fluid 2 is filled only after the radiation fins 11 have been integrally connected to the base 12 through overmolding without leaving any clearance between the radiation fins 11 and the base 12 to avoid the occurrence of any thermal resistance. Then, the chambers 113 are filled with the working fluid 2 and vacuum evacuated before being sealed. In this manner, the working fluid 2 in the chambers 113 would not be vaporized at the high temperature when the radiation fins 11 are integrally connected to the base 12 through overmolding.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A heat sink structure, comprising:
a plurality of radiation fins respectively having a connecting end and a free end; each of the radiation fins internally defining a chamber extended between the connecting end and the free end, and the chambers having a working fluid filled therein; and
a base having an upper and a lower side serving as a connecting surface and a heat receiving surface, respectively; the heat receiving surface being in contact with a heat source, and the connecting surface being integrally connected to the connecting ends of the radiation fins through overmolding.

2. The heat sink structure as claimed in claim 1, wherein the connecting surface has a plurality of connecting sections integrally formed thereon; the connecting ends of the radiation fins being extended into and accordingly integrally connected to the connecting sections through overmolding, such that the connecting ends are enclosed in the connecting sections in one-to-one correspondence, allowing the radiation fins to be stably and integrally connected to the base.

3. The heat sink structure as claimed in claim 1, wherein the working fluid is selected from the group consisting of a gas and a liquid.

4. The heat sink structure as claimed in claim 1, wherein the radiation fins and the base may be made of the same or different materials.

5. The heat sink structure as claimed in claim 1, wherein the radiation fins are subjected to working fluid filling and vacuum evacuation only after the radiation fins have been integrally connected to the base through overmolding.
